(19) United States
(12) Patent Application Publication
(10) Pub. No.: US 2025/0154679 A1
(43) Pub. Date: May 15, 2025

(54) METHOD FOR MANUFACTURING SAPPHIRE BARS

(71) Applicant: Comadur SA, Le Locle (CH)

(72) Inventor: Didier COCHET-MUCHY, Hurtière (FR)

(73) Assignee: Comadur SA, Le Locle (CH)

(21) Appl. No.: 18/766,019

(22) Filed: Jul. 8, 2024

(30) Foreign Application Priority Data
Nov. 9, 2023 (EP) 23208878.1

(51) Int. Cl. C30B 13/32; C30B 13/08; C30B 29/20

(52) U.S. Cl. CPC C30B 13/32; C30B 13/08; C30B 29/20

(57) ABSTRACT

A method for manufacturing monocrystalline sapphire directly in bar form, the method comprising the following steps of: providing a crucible (100), the crucible having a sapphire piece forming a seed for sapphire growth; placing the crucible (100) in an enclosure (4) under vacuum or a controlled atmosphere and heating the enclosure (4) to bring the crucible up to operating temperature; feeding the crucible with raw material (M) via a feed system (3) to form molten raw material (F) in the crucible; gradually solidify the molten raw material and gradually form a sapphire bar (C); interrupting the feed of raw material (M) and completely crystallising the molten material (F) remaining in the crucible; cooling the crucible to ambient temperature; recovering the sapphire bar bonded to the resulting seed, the seed and/or a portion of the bar, after being sawn, being able to form both a new back and a new seed.

### CROSS REFERENCE TO RELATED APPLICATIONS

This application is claims priority to European Patent Application No. 23208878.1, filed on Nov. 9, 2023, the disclosures of which are incorporated by reference herein their entireties

### TECHNICAL FIELD OF THE INVENTION

The present invention relates to a method for manufacturing monocrystalline sapphire directly in bar form. The present invention further relates to external and functional components for the watchmaking and jewellery industries cut from such a sapphire monocrystal.

### TECHNOLOGICAL BACKGROUND

Several methods exist for obtaining an artificial monocrystal:
from a supersaturated solution of the compound;
from the molten compound;
by chemical vapour transport.

The Verneuil method is a well-known example. To synthesise the corundum with the formula Al₂O₃ that makes up rubies and sapphires, the temperature must be raised to a very high level (fusion at 2050° C.), a temperature that is reached by means of an oxyhydrogen torch H₂+½O₂→H₂O with a flame temperature of around 2700° C. Alumina, which can be doped, is inserted in the form of a fine powder by a vibrator, which drops small quantities directly into the flame of the torch. The drop of molten alumina thus formed falls to the top of the seed and crystallises according to the crystallographic arrangement of that seed. The growing monocrystal is gradually lowered so that crystallisation takes place at a constant temperature. At the end of the synthesis, a bottle-shaped monocrystal is obtained.

Nevertheless, sapphire monocrystals obtained by the Verneuil method exhibit high dislocation densities and uncontrollable local disorientations. Other defects also present in Verneuil monocrystals, such as bubbles, rain and other inclusions, are likely to be visible to the naked eye, for example in a finished watch crystal.

Furthermore, effective control over the shape of Verneuil crystals is relatively poor, at best+/−2 mm over the diameter.

The Czochralski method is a crystallisation technique using a molten bath in a crucible. In theory, it is well suited to the production of cylindrical sapphire, whose size is limited only by that of the crucible. As the pulling speed is precisely controlled, the average diameter can be kept very close to the desired value by means of a sensor weighing the crystal, which weight measurement is used to calculate the deviation from this diameter and regulate the crystallisation temperature accordingly.

However, control over the mean diameter does not prevent the actual shape of the sapphire crystal from deviating significantly from the ideal cylinder in some cases. As the growing crystal is free of any contact with the crucible, there is no mechanical constraint limiting its shape. Facets, flat surfaces of lower energy, can appear in relation to the pulling orientation. In some cases, such as growth along the A axis, facets perpendicular to C appear, which can lead to a very pronounced shape anisotropy.

It should also be noted that the Czochralski technique requires a very high sapphire bath, since all of the raw material used to form the crystal must be contained in the crucible, which makes it more difficult to degas. Bubbles and micro-bubbles can potentially find their way into the crystal as it grows above the bath.

In the EFG (Edge-defined Film-fed Growth) technique, sapphire crystallisation takes place at the top of a die, immersed in a bath of molten sapphire. The die gives the crystal produced its profile. Plates, tubes and small bars can be obtained in order to near the final dimensions. However, as the molten sapphire has to rise to the top of the die via a very thin capillary channel (maximum 0.8-1 mm in one dimension), the profile will also have a limited thickness dimension, typically 20 mm at most. Moreover, as crystallisation takes place above the bath, the bubbles formed therein and the dissolved gases will be able to rise up into the crystal. In particular, micro-bubbles will systematically appear near the surfaces, typically to a depth of 0.5 mm, which limits the useful part of the sapphire produced and requires all of the surfaces to be machined to this depth.

In the Micro-Pulling-Down technique, crystallisation of the sapphire takes place below the molten sapphire bath, which limits the problems involving the incorporation or nucleation of bubbles and micro-bubbles mentioned above. However, the crystallisation zone is always fed by capillary action, i.e. a thin hole or slit drilled in the back of the crucible containing the sapphire bath, under which hole or slit a sapphire seed must be brought so that a stable liquid meniscus forms between the crucible and this seed. The conditions for meniscus stability are reduced as its surface area increases, which unfortunately greatly limits the dimensions accessible by Micro-Pulling-Down.

Horizontal and vertical Bridgman crystallisation techniques, and their variants (HDC—Horizontal Directional Crystallisation or Bagdasarov, HEM—Heat Exchanger Method, VGF—Vertical Gradient Freeze, etc.) are all characterised by the fact that the crystal grows directly in contact with the crucible, which thus precisely determines the shape of the sapphire obtained, allowing this shape to resemble the shapes of the final product as closely as possible. However, this advantage has a drawback in terms of cost, since the crucible typically has to be destroyed to recover the crystal and has to be renewed for each crystallisation cycle. Moreover, all of the raw material intended to form the crystal must be contained in the crucible and fused completely, so the height of the bath can be significant and as a result an obstacle to efficient degassing in terms of the optical quality of the crystal.

### SUMMARY OF THE INVENTION

The aim of the present invention is to overcome the above and other problems by providing a method for manufacturing sapphire monocrystals directly in bar form.

Such a method allows the crystallisation of sapphire directly in the form of bars of easily adaptable and precisely controllable cross-section and length to be optimised, without resorting to capillary effects limiting one of the three dimensions, and nearing as much as possible the final dimensions required, in particular those of timepiece components, and that is also easily sawn into slices by wire sawing, all of which makes it possible to considerably reduce material losses during machining.

The invention also aims to allow the method tools to be reused multiple times in order to reduce costs.

The invention also aims to optimise the optical quality of the crystals produced by controlling the atmosphere in which the method is carried out and by limiting the quantity of molten bath to facilitate its degassing.

Finally, the invention aims to optimise the optical quality of the crystals produced by growing the crystal below the molten bath, in order to limit the incorporation into the crystal of bubbles, microbubbles and residual gases in the bath.

To this end, the present invention relates to a method for manufacturing a monocrystalline sapphire in bar form, the method comprising the following steps of:
providing a crucible, the crucible comprising a first stationary part with an internal opening, and a second movable part forming the back of the crucible and consisting of a sapphire piece forming a seed for sapphire growth;
positioning the first part and the second part relative to each other at ambient temperature, the second part being translatably movable in the internal opening of the first part;
placing the crucible in a vacuum or controlled atmosphere enclosure and heating the enclosure to bring the crucible up to operating temperature;
feeding raw material into the crucible, preferably via a tank and a feed system operating continuously or non-continuously, to form molten raw material in the crucible, above the movable sapphire part;
moving the back of the crucible translatably towards the lower, less heated zone by means of translation means, at a controlled speed, in order to gradually solidify the molten raw material and gradually form a sapphire bar having the same cross-section as the back of the crucible;
interrupting the feed of raw material and completely crystallising the molten material remaining in the crucible;
cooling the crucible to ambient temperature;
recovering the sapphire bar obtained, a portion of the bar, after being sawn, being able to form both a new back and a new seed.

According to particular implementations of the method according to the invention:
the internal opening of the first part is cylindrical and has a cross-section substantially corresponding to the desired cross-section of the sapphire bar;
the sapphire back is cylindrical in shape and has a cross-section corresponding to the desired cross-section of the sapphire bar;
the first part of the crucible is made of a refractory metal such as molybdenum, tungsten or an alloy of these two metals;
the operating temperature of the enclosure is between 2000° C. and 2100° C.;
the first and second parts are dimensioned to achieve minimum clearance when at operating temperature;
the raw material has a pure or doped Al2O3 chemical composition;
the raw material is selected from ground cracked sapphire, sapphire or alumina beads, or densified and compacted alumina powder in the form of pellets;
the controlled atmosphere is composed of a neutral gas;
the neutral gas is argon;
movement is controlled by a motorised translation system;
the capacity of the raw material feed tank is at least equal to that of the weight of the sapphire bar that can be crystallised;
the crystallographic orientation of the back or seed of sapphire can be chosen indistinctly from all of the crystallographic orientations of sapphire;
once the sapphire bar has been obtained, external or functional components for the watchmaking and jewellery industries are cut from it;
this sapphire bar is wire-sawn to produce external or functional components for the watchmaking and jewellery industries;
the same vacuum or controlled atmosphere enclosure is used for a plurality of crucibles, heating systems, raw material feeds and translation means.

The invention further relates to external and functional components for the watchmaking and jewellery industries, in particular bridges, plates, crystals, watch cases and dials or bracelet links, cut from a sapphire monocrystal obtained in accordance with the method of the invention.

Thanks to these features, the present invention provides a method that makes it possible to manufacture watch crystals under easier machining conditions and with minimal losses.

### BRIEF DESCRIPTION OF THE FIGURES

Other features and advantages of the present invention will become clearer from the following detailed description of an example embodiment of the method according to the invention, this example being given purely by way of non-limiting illustration in connection with the accompanying drawing in which:

FIG. 1 illustrates the second step of the method according to the invention;

FIG. 2 illustrates the third step of the method according to the invention;

FIG. 3 illustrates the comparative expansion coefficients of molybdenum, tungsten and sapphire as a function of temperature (according to C. Miyogawa et al, J. Cryst. Growth 372 (2013) pages 95-99);

FIG. 4 illustrates the fourth and fifth steps of the method according to the invention;

FIG. 5 illustrates a schematic diagram of a furnace for growing a plurality of sapphire bars in parallel.

### DETAILED DESCRIPTION OF THE INVENTION

This invention relates to a method for manufacturing (or crystallising) monocrystalline sapphire directly in bar form.

The first step of the method consists in setting up a crucible 100 intended to receive a raw material “M”, where it is melted by supplying heat.

The raw material “M” used to manufacture sapphire has the chemical composition Al₂O₃ and is either pure or doped. The raw material “M” can be chosen from ground cracked sapphire, sapphire or alumina beads, or densified and compacted alumina powder in the form of pellets.

According to the invention, the crucible 100 comprises a first stationary part 1 with an internal opening 13, and a second movable part 2 forming the back of the crucible and consisting of a sapphire piece forming a seed for sapphire growth.

The back 2 of the crucible can be between 1 cm and 10 cm thick.

In an alternative embodiment, an intermediate metal part can also be provided, which part forms a circular metal back to which the seed is fastened.

As illustrated, the internal opening 13 of the first part 1 is cylindrical, extends over the height of the first part, and has a cross-section corresponding substantially to the cross-section of the sapphire bar to be manufactured. Similarly, the sapphire back 2 is cylindrical in shape and has a cross-section corresponding to the desired cross-section of the sapphire bar. The shape and size of the cylinder will precisely define the shape and size of the sapphire bars to be crystallised.

It goes without saying that the internal opening 13 can have a wide variety of cross-sectional shapes relative to the longitudinal axis of the crucible, and the shape of the cross-section depends on the cross-section of the sapphire crystal to be produced.

The internal cross-section can thus be circular, oval or polygonal. The polygonal cross-section can, for example, take the form of a square, a rectangle, a pentagon, a hexagon or an octagon.

The first part 1 of the crucible 100 is preferably made of a refractory metal such as molybdenum, tungsten or an alloy of these two metals.

The next step in the method is to position the first part 1 and the second part 2 relative to each other at ambient temperature, with the second part 2 translatably movable in the internal opening 13 of the first part.

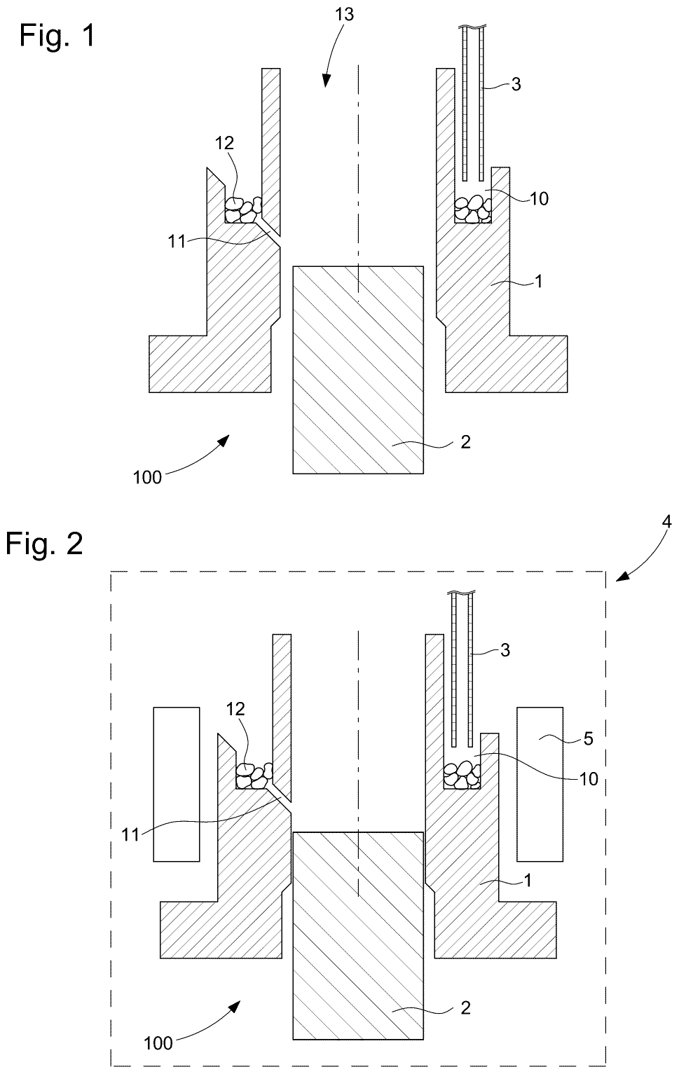

The first metal part 1 of the crucible and the sapphire back 2 of the crucible (or seed) must be positioned in relation to each other when the system is still at ambient temperature. To allow this, there must be sufficient space between the two parts of the same shape, as shown in FIG. 1.

In the next step, the crucible 100 is placed in an enclosure 4 under a vacuum or controlled atmosphere and is heated via a heating system 5 to bring it up to operating temperature. The operating temperature in the crucible is between 2000° C. and 2100° C., and is preferably at least 2050° C. at the top of the back 2, the temperature at which sapphire melts.

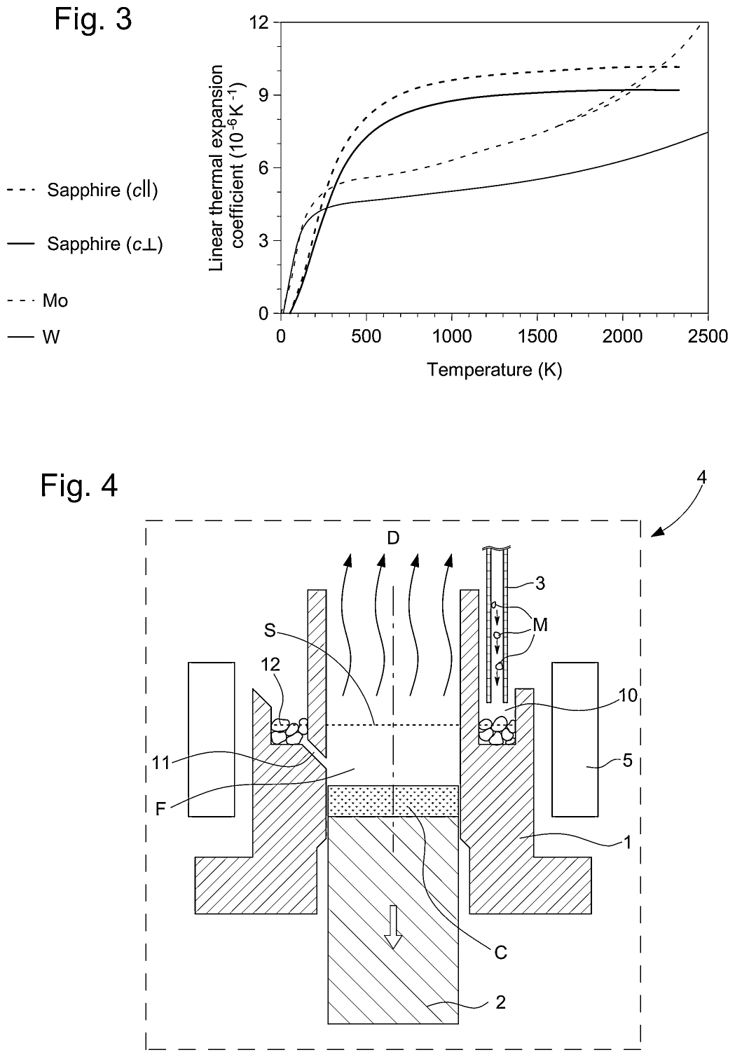

When the crucible 100 is at operating temperature, a temperature very slightly above the sapphire melting temperature of 2050° C. must be reached at the surface of the seed. The first metal part 1 and the second sapphire part will thus both have expanded with the rise in temperature. However, the metal part 1 will have expanded less than the sapphire back 2, as can be seen from the expansion coefficient curves for these two materials in FIG. 3. It is thus possible to calculate the respective dimensions of the two parts in order to achieve virtually zero clearance between the two parts at operating temperature. This arrangement ensures that the assembly is impervious to flows of molten sapphire and that the back 2 (or sapphire seed) can be driven downwards, sliding in the internal opening 13 of the first metal part of the crucible, which remains stationary.

The rest of the method consists of feeding the crucible 100 thus formed with raw material “M” to transform it into molten raw material “F”, in a relatively small quantity at any one time. The zone of liquid (or molten) sapphire above the seed is thus relatively thin, and has an exchange surface “S” with the atmosphere of the enclosure in which the system is placed, equal to the cross-section of the cylinder and comparatively relatively large.

Thus, it is possible to maximise the degassing “D” of the liquid sapphire. In order to be compatible with the use of molybdenum or tungsten metals or an alloy of these two metals at high temperature, the enclosure in which the method is carried out is an airtight enclosure in which a high vacuum or complete evacuation of the air by a neutral gas has been carried out beforehand.

To maintain a zone of molten sapphire raw material F in a relatively small constant quantity at all times, a feed system 3 is preferably used, which feed can be continuous or non-continuous.

A continuous feed system 3 allows the raw material M to be supplied in a finely divided form, and thus allows the quantity supplied to be precisely regulated at any one time, so that it corresponds precisely to the quantity crystallised at the same time.

The melting of the raw material M preferably takes place in a zone that is separate from the zone directly above the seed, so as not to disrupt crystallisation. Advantageously, a receiving groove 10 forming a melting zone is provided on the external face around the first metal part 1 of the crucible and communicates with the internal opening 13 via feed channels 11, as can be seen in FIGS. 1, 2 and 4. This melting zone is advantageously lined with metal chips, splinters, granules, pellets or capsules 12, such as molybdenum or tungsten, on which the raw material M is melted.

The molten raw material F then flows into the internal opening 13 of the crucible via the channels 11. This arrangement provides an additional degassing effect.

The rest of the method can still be carried out in a vacuum with continuous pumping P, or in an atmosphere of argon or another neutral gas, but preferably at a reduced pressure and with continuous pumping P to promote degassing of the molten sapphire.

Moreover, a heating and insulation environment free of carbon (C) is preferably used to avoid the formation of carbon monoxide (CO) gases that can dissolve in the molten sapphire, so metallic heating elements are preferred.

The next step consists of translating the back 2 of the crucible at a controlled speed, to gradually solidify the molten raw material F and gradually form a sapphire monocrystal C in the form of a bar. This movement takes place towards the lower, less heated, and thus cooler, zone in the enclosure 4, to solidify the molten raw material.

Crystallisation of the sapphire is achieved by the translation, at a speed controlled by a motorised translation system 6, of the back 2 of the crucible (i.e. the sapphire seed) downwards, the first metal part 1 of the crucible being supported by a structure integral with the enclosure 4 and thus remaining stationary during manufacture of the sapphire monocrystal.

The molten raw material F (or liquid sapphire) at the interface with the back 2 is thus displaced into a colder zone and solidifies while retaining the orientation and profile of the back 2 of the crucible (i.e. the seed). Any bubbles and dissolved gases, if still present and if the displacement does not occur too quickly, are not incorporated into the crystallised sapphire.

The position of the liquid/solid interface remains substantially constant throughout the method. The length of the crystallisable sapphire bar depends on the total travel of the translation system, whereby the capacity of the raw material tank must be at least equal to that of the weight of the crystallisable bar.

The method is completed by interrupting the supply of raw material M and by the complete crystallisation of the molten sapphire zone, followed by cooling of the crucible 100 to ambient temperature.

Once everything has cooled, the sapphire bar C bonded to the seed 2 can be recovered, and the seed 2 and/or a portion of the bar C can be sawn to form a new back 2 and thus a new seed.

Thus, the method can be repeated by placing a new back or seed in the same first metal part of the crucible. This new seed can simply be the seed used initially and/or a small portion of the bar obtained, recovered by sawing. The seed can thus be regenerated indefinitely, without the need for complicated re-machining operations to obtain a back (or seed) of the correct dimensions.

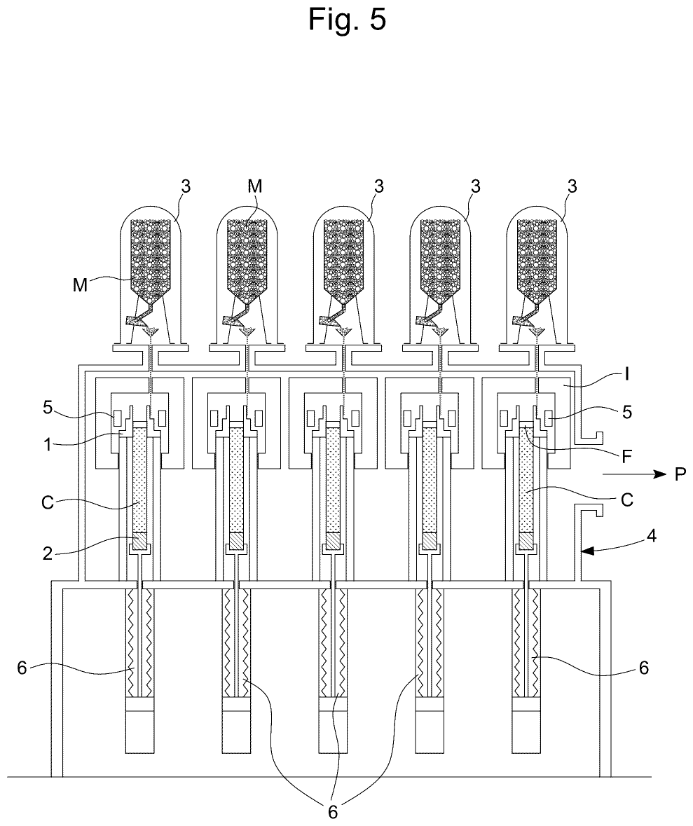

FIG. 5 illustrates an example of a device for manufacturing a sapphire monocrystal directly in the form of a bar. A single enclosure under vacuum or a controlled atmosphere can include a plurality of crucibles and seeds, and as many heating systems, insulation systems, continuous raw material feed systems and translation systems, operating in parallel, to increase the production of sapphire bars by this method at lower cost.

The present invention also allows watch crystals and backs to be manufactured from a sapphire bar obtained using the method described above. It goes without saying that this example is purely illustrative and not limitative, and that the manufacture of external and functional components, particularly for the watchmaking and jewellery industries, such as bridges, plates, watch cases and dials or bracelet links, is also possible.

1. A method for manufacturing monocrystalline sapphire directly in bar form, the method comprising the following steps of:
providing a crucible (100), the crucible comprising a first stationary part (1) with an internal opening (13), and a second movable part (2) forming the back of the crucible and consisting of a sapphire piece forming a seed for sapphire growth;
positioning the first part (1) and the second part (2) relative to each other at ambient temperature, the second part being translatably movable in the internal opening (13) of the first part;
placing the crucible (100) in an enclosure (4) under vacuum or a controlled atmosphere and heating the enclosure (4) to bring the crucible up to operating temperature;
feeding the crucible with raw material (M) via a feed system (3) to form molten raw material (F) in the crucible, above the movable sapphire part;
moving the back (2) of the crucible translatably via movement means, at a controlled speed, to gradually solidify the molten raw material and gradually form a sapphire bar (C) having the same cross-section as the back (2) of the crucible (100);
interrupting the feed of raw material (M) and completely crystallising the molten material (F) remaining in the crucible;
cooling the crucible to ambient temperature; and
recovering the sapphire bar bonded to the seed.

2. The method for manufacturing monocrystalline sapphire according to claim 1, wherein the internal opening (13) of the first part is cylindrical and has a cross-section substantially corresponding to the desired cross-section of the sapphire bar.

3. The method for manufacturing monocrystalline sapphire according to claim 1, wherein the sapphire back (2) is cylindrical in shape and has a cross-section corresponding to the desired cross-section of the sapphire bar.

4. The method for manufacturing monocrystalline sapphire according to claim 1, wherein the first part (1) of the crucible is made of a refractory metal such as molybdenum, tungsten or an alloy of these two metals.

5. The method for manufacturing monocrystalline sapphire according to claim 1, wherein the operating temperature in the crucible (100) is between 2000° C. and 2100° C.

6. The method for manufacturing monocrystalline sapphire according to claim 1, wherein the first part (1) and the second part (2) are dimensioned to achieve a minimum clearance when at operating temperature.

7. The method for manufacturing monocrystalline sapphire according to claim 1, wherein the raw material (M) has a pure or doped Al₂O₃ chemical composition.

8. The method for manufacturing monocrystalline sapphire according to claim 7, wherein the raw material (M) is chosen from ground cracked sapphire, sapphire or alumina beads, or densified and compacted alumina powder in the form of pellets.

9. The method for manufacturing monocrystalline sapphire according to claim 1, wherein the controlled atmosphere is composed of a neutral gas.

10. The method for manufacturing monocrystalline sapphire according to claim 9, wherein the neutral gas is argon.

11. The method according to claim 1, wherein the translation means are managed by a motorised translation system (6).

12. The method according to claim 1, wherein the capacity of the system (3) for feeding raw material (M) is at least equal to that of the weight of the crystallisable sapphire bar.

13. The method according to claim 1, wherein the crystallographic orientation of the sapphire back or seed can be chosen indistinctly from all of the crystallographic orientations of sapphire.

14. The method according to claim 1, wherein, once the sapphire bar has been obtained, external or functional components for the watchmaking and jewellery industries are cut from this sapphire bar.

15. The method according to claim 14, wherein the external or functional components for the watchmaking and jewellery industries are cut from this sapphire bar by wire sawing.

16. The method according to claim 1, wherein the same enclosure under vacuum or a controlled atmosphere is used for a plurality of crucibles, heating systems, raw material feed systems and translation means.

17. External and functional components for the watchmaking and jewellery industries cut from a sapphire monocrystal obtained by carrying out the manufacturing method according to claim 1.

18. The external and functional components according to claim 17, wherein the components are bridges, plates, crystals, watch cases and dials or bracelet links.

19. The method according to claim 1, further comprising sawing off the seed and/or a portion of the bar to form both a new back and a new seed.
